(19) United States
(12) Patent Application Publication
(10) Pub. No.: US 2024/0378354 A1
(43) Pub. Date: Nov. 14, 2024

(54) Methods And Systems For Use In Trait Interpretation In Agricultural Crops

(71) Applicant: MONSANTO TECHNOLOGY LLC, Saint Louis, MO (US)

(72) Inventors: Neal CARPENTER, Wildwood, MO (US); Srinivas Phani Kumar CHAVALI, Chesterfield, MO (US); Bhaskar DUTTA, Saint Peters, MO (US); David Paul FLEMING, Webster Groves, MO (US); Sambuddha GHOSAL, Saint Louis, MO (US); Megan Eileen GILLESPIE, Wildwood, MO (US); Adam GOLD, Wildwood, MO (US); Wei-Ting LIAO, Ballwin, MO (US); Chenyong MIAO, Saint Louis, MO (US); Ethan Marcus PICKERING, Boston, MA (US); Kai-Wei YANG, Chesterfield, MO (US)

(21) Appl. No.: 18/658,888

(22) Filed: May 8, 2024

Related U.S. Application Data
(60) Provisional application No. 63/465,239, filed on May 9, 2023.

(51) Int. Cl. G06F 30/27; A01B 79/00; A01C 7/10

(52) U.S. Cl. CPC G06F 30/27; A01B 79/005; A01C 7/102

(57) ABSTRACT

Example systems and methods are disclosed for use in interpreting traits of interest in agricultural crops. One example computer-implemented method includes compiling multiple data sets including a first mode of data and a second mode of data, and accessing a simulation architecture, which includes a mode layer and an aggregate layer connected to the mode layer, where the mode layer includes a first model and a second model. The method also includes inputting the first mode of data to the first model and the second mode of data to the second model, whereby latent feature data is generated by the mode layer and input to the aggregate layer, and then presenting an output, from the simulation architecture, which includes a trait of interest based on the first mode of data and/or the second mode of data.

### CROSS-REFERENCE TO RELATED APPLICATION

This application claims the benefit of, and priority to, U.S. Provisional Application No. 63/465,239, filed on May 9, 2023. The entire disclosure of the above-referenced application is incorporated herein by reference.

### FIELD

The present disclosure generally relates to methods and systems for use in trait interpretation in agricultural crops, and, in particular, to methods and systems for use in interpreting traits of interest to be expressed, or included, in agricultural crops.

### BACKGROUND

This section provides background information related to the present disclosure which is not necessarily prior art.

Modification of plants are known to be made, often through selective breeding or genetic manipulation. Based on the particular modifications, resulting plants may exhibit a desired feature (or features). The feature(s) may be tested across a variety of different environments, and when the feature(s) is/are confirmed, the modified plants may be advanced for further development of the plants and/or for commercial implementation, whereby the plants are bulked and sold to growers.

### SUMMARY

This section provides a general summary of the disclosure and is not a comprehensive disclosure of its full scope or all its features.

Example embodiments of the present disclosure generally relate to systems for use in interpreting traits of interest in agricultural crops. In one example embodiment, such a system generally includes a computing device including a memory and at least one processor, wherein the memory includes executable instruction and a simulation architecture, which includes a mode layer and an aggregate layer. The mode layer includes at least one first model for a first mode and at least one second model for a second model for a second mode, where each of the at least one first model and the at least one second model is configured to output latent feature data, specific to the first mode and the second mode, respectively, to the aggregate layer. The at least one processor is configured, by the executable instructions to: access data from the memory, the accessed data including first data specific to the first mode and second data specific to the second mode; input the first data to the at least one first model and the second data to the at least one second model; and generate, via the simulation architecture, an output indicative of the first data and the second data.

Example embodiments of the present disclosure also generally relate to methods for use in interpreting traits of interest in agricultural crops. In one example embodiment, such a method generally includes compiling multiple data sets including a first mode of data and a second mode of data; accessing a simulation architecture, which includes a mode layer and an aggregate layer connected to the mode layer, the mode layer including a first model and a second model; inputting the first mode of data to the first model and the second mode of data to the second model, whereby latent feature data is generated by the mode layer and input to the aggregate layer; and presenting an output, from the simulation architecture, which includes a trait of interest based on the first mode of data and/or the second mode of data.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments, are not all possible implementations, and are not intended to limit the scope of the present disclosure.

FIG. 1 is an example system of the present disclosure suitable for interpreting traits in agricultural crops;

FIGS. 2A-2C are graphics of example simulation architectures that may be used in the system of FIG. 1, each of which includes multiple modes of different data in respective mode layers therein for use in interpreting traits in agricultural crops;

FIG. 3 is a block diagram of an example computing device that may be used in the system of FIG. 1; and

FIG. 4 is an example method, suitable for use with the system of FIG. 1, for interpreting traits in agricultural crops, through use of a simulation architecture based on multiple different modes in a mode layer, and then based on an aggregate layer.

Corresponding reference numerals indicate corresponding parts throughout the several views of the drawings.

### DETAILED DESCRIPTION

Example embodiments will now be described more fully with reference to the accompanying drawings. The description and specific examples included herein are intended for purposes of illustration only and are not intended to limit the scope of the present disclosure.

In connection with plant breeding, a number of different techniques may be used to promote desired traits in plants. The techniques often rely on specific decisions, which predict, essentially, the expected performance of the plants being modified, at least to one specific trait (e.g., yield, etc.). In this manner, given hundreds of thousands of potential plants, origins, etc., decisions to account for expected trait performance range into the trillions, if not billions of decisions per experiment. The decisions also become reliant on testing of some of the decisions, which then contribute to other decisions, whereby physical, biological resources allocated to the breeding decisions are often substantial.

Uniquely, the methods and systems herein provide for interpretation of traits of an agricultural crop based on a multi-model architecture, whereby the substantial number of decisions may be accounted for through the architecture.

In particular, different modes of data are accessed (e.g., for agricultural crops, etc.), and provided as input to a simulation architecture, and specifically, different modal models of a mode layer of the architecture. Each of the modes of data is transformed, in the mode layer, separately, into latent feature data. The latent feature data is then input to an aggregation layer of the simulation architecture. The aggregate layer combines the different latent feature data to interpret one or more traits of the agricultural crop represented by the mode of data. In this manner, the multi-modal simulation architecture individually relies on the modes of agricultural data, in a mode layer, and then aggregates the latent feature data, to predict traits of the agricultural crop. As such, the simulation architecture provides for specific and accurate simulation of one or more traits of interest in the agricultural crop, whereby efficiencies may be gained in prediction, placement, breeding, and/or physical creation of the crops for one or more specific environments, or otherwise. For example, breeding decisions, placement decision, and/or other related decisions may be made earlier, based on the simulation, alone or in combination with planting and/or developing the crops, etc.

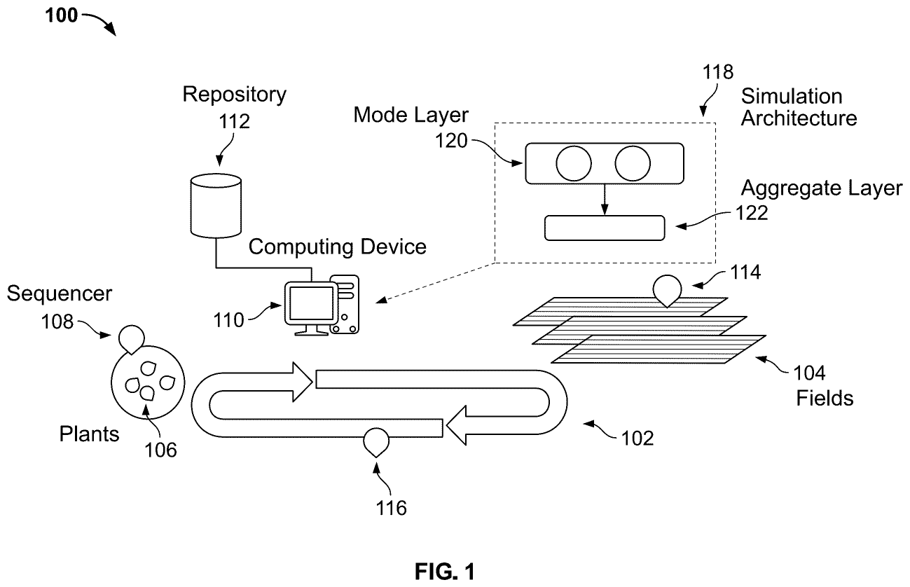

FIG. 1 illustrates an example system 100 for interpreting traits for agricultural crops based, at least in part, on different modes of data, in which one or more aspects of the present disclosure may be implemented. Although, in the described embodiment, parts of the system 100 are presented in one arrangement, other embodiments may include the same or different parts arranged otherwise depending, for example, on available data (e.g., different modes of data, etc.), types of crops, traits of interest, implementation of predictions, etc.

As shown in FIG. 1, the system 100 generally includes a plant breeding architecture 102, which is provided to identify plants, assess plants, and/or advance plants for purposes related to plant development and/or commercialization, etc. In general, as shown, the plant breeding architecture 102 includes a cyclical process, by which plants are produced, grown and tested, and later generations are produced, grown and tested, as explained below, and also potentially, in this example embodiment, simulated.

In this example embodiment, the plant breeding architecture 102 includes a series of fields 104 (e.g., growing spaces, etc.), which are located in one or more regions. The fields 104 as suited for growing one or more different types of plants 106 (as part of the plant breeding architecture 102). The fields 104 may include tens, hundreds, thousands or more or less fields, covering tens, hundreds, thousands, or more or less acres (e.g., they may have any suitable size, etc.), individually or in aggregate, etc. The fields 104, accordingly, may be less than an acre in some examples (e.g., which may be referred to as plots, etc.), or more than an acre in other examples, or even more than several acres in still other examples. The fields 104 may be outside and exposed to natural conditions (e.g., weather, etc.), or inside (e.g., greenhouses, etc.) and subject to planned conditions. The fields 104 therefore may include any different types or sizes of growing spaces for the plants 106.

The plant breeding architecture 102 also includes various different types of plants 106, which may be any suitable variety, type, etc., of plants. The plants 106 may be of the same type and/or variety, for example, corn or maize, or may be different types or varieties, etc. In general, the plants 106 may include, without limitation, soybean (Glycine max), cotton (Gossypium hirsutum), peanut (Arachis hypogaea), barley (Hordeum vulgare); oats (Avena sativa); orchard grass (Dactylis glomerata); rice (Oryza sativa, including indica and japonica varieties); sorghum (Sorghum bicolor); sugar cane (Saccharum sp); tall fescue (Festuca arundinacea); turfgrass species (e.g., species: Agrostis stolonifera, Poa pratensis, Stenotaphrum secundatum, etc.); wheat (Triticum aestivum), and alfalfa (Medicago sativa), members of the genus Brassica, including broccoli, cabbage, cauliflower, canola, and rapeseed, carrot, Chinese cabbage, cucumber, dry bean, eggplant, fennel, garden beans, gourd, leek, lettuce, melon, okra, onion, pea, pepper, pumpkin, radish, spinach, squash, sweet corn, tomato, watermelon, honeydew melon, cantaloupe and other melons, banana, castorbean, coconut, coffee, cucumber, Poplar, Southern pine, Radiata pine, Douglas Fir, Eucalyptus, apple and other tree species, orange, grapefruit, lemon, lime and other citrus, clover, linseed, olive, palm, Capsicum, Piper, and Pimenta peppers, sugarbeet, sunflower, sweetgum, tea, tobacco, and other fruit, vegetable, tuber, and root crops, etc. Repository 112 may include data related to non-crop species, especially those used as model methods and/or systems, such as Arabidopsis, etc.

In general, the plants 106 may be of one type, i.e., corn versus soybean, for purposes herein, whereby the type of plants 106 may still include several different varieties of that type of plant (e.g., hundreds or thousands or millions of varieties of corn, etc.).

As used herein, plants 106 should be understood to be inclusive of any different type of plant material at any stage of development or growth, whereby the plants 106 may include origins, progenies, hybrids, seeds, etc., or the plants 106 may include plants growing in the fields 104, or the plants 106 may include plant materials harvested from the fields 104. In one or more instances, the specific usage of the term “plant” herein may be specific to a growth stage, or development stage of the plants 106, based on the usage of the term (e.g., growing of the plant, etc.), but should, generally, be understood to be consistent with the broader definition above.

Prior to planting, the plants 106 may be subject to one or more processes, by which genotypic data is determined, either through testing or reference to known data related to the plants 106. As shown, the plant breeding architecture 102 includes a genotypic mechanism, or more specifically, a sequencer 108, which is configured to determine the sequence the plants 106 and to output genotypic data for the plants 106. The genotypic data, or more broadly, plant data, is received by a computing device 110, from the sequencer 108 (directly or indirectly), and stored, by the computing device 110, in repository 112. The genotypic data is associated with identifying data for the plants 106 (e.g., plant identifiers, etc.), for example, to identify the specific genotypic data to the specific one of the plants 106.

The genotypic data may include a specific representation of features or markers of one or more sequences of the DNA of the plants 106. The markers may include any suitable number of base pairs from the sequence(s), and what's more, the sequence(s) may be represented as a specific vector or matrix depending on the specific plant 106 (e.g., hybrid included genotypic data for male and female lines, etc.).

In the embodiment of FIG. 1, various plants 106 are planted in one or more of the fields 104, as seeds, and grown toward maturity. The plants 106 are grown in the fields 104 and measured by various sensors 114 (e.g., temperature sensors, moisture sensors, soil sensors, etc.), which are configured to measure one or more types of phenotypic data about the plants 106 in the fields 104, and by various sensors 116, which are configured to measure one or more types of phenotypic data about the plants 106 after harvest from the fields 104 (e.g., as part of or within the breeding architecture 102, etc.) (e.g., imaging devices, moisture sensors, etc.). The phenotypic data may be specific to a trait of the plant 106, where the trait of interest may include, without limitation, size and/or heartiness (e.g., plant height, car height, standability, sustainability, stalk girth, stalk strength, etc.), yield of the plant 106, time to maturity, resistance to stress(es) (e.g., disease or pest resistance, etc.), resistance to abiotic stress(es) (e.g., drought or salinity resistance, etc.), growing climate, or any other suitable phenotypic data, and/or combinations thereof. The trait of interest may additionally, or alternatively, include, without limitation, yield, thousand kernel weight, saleable seed units, average seed pixel area, tassel size and skeletonization, grey leaf spot, anthracnose, goss's wilt, diplodia, fusarium, gibberella, northern leaf blight, brown/southern rust, tar spot, greensnap, moisture, plant height, lodging, chloride, southern stem canker, white mold, sudden death syndrome, soybean cyst nematode, root knot nematode, phytophthora, iron deficiency chlorosis, frogeye leaf spot, brown steam rot, maturity, and/or combinations thereof. The phenotypic data, or more broadly, plant data, is received by the computing device 110, from the sensors 114, 116, and stored, by the computing device 110 in the repository 112. The phenotypic data is associated with identifying data for the plant (e.g., the plant identifiers for the plants 106, etc.), for example, to identify the specific phenotypic data to the specific one of the plants 106 and/or specific fields 104.

While the plants 106 are growing in the fields 104, the fields 104 (depending on the type(s) of fields 104) often experience various different types of weather, from precipitation to sunshine, to wind, or other conditions, etc. In this example embodiment, the sensors 114 are configured to also capture the weather data indicative of the conditions at the fields 104, and to communicate the weather data to the computing device 110, which in turn is configured to store the weather data in the repository 112. The weather data is associated with identifying data for one or more of the fields 104 (e.g., via field identifier, etc.), for example, to identify the specific weather data, over time, to the specific field(s).

The weather data, for example, may include, without limitation, atmospheric pressure (e.g., average, minimum, maximum, etc.), wind (e.g., maximum gust, minimum speed, maximum speed, average speed, direction, etc.), precipitation (e.g., rate, maximum rate, average rate, volume, etc.), solar radiation (e.g., total, maximum net radiation, etc.), cloud cover (e.g., average, etc.), snow (e.g., cover, depth, density, etc.), soil temperature at different levels (e.g., levels 1-4, etc.) (e.g., average, minimum, maximum, etc.), soil moisture at different levels, temperature (e.g., minimum, maximum per interval (e.g., day, hour, etc.), etc.), dew point temperature (e.g., average, minimum, maximum, etc.), relative humidity (e.g., average, minimum, maximum, etc.), etc. The weather data may be expressed in a time-series over a regular or irregular interval.

Similarly, before, during or after the growing of the plants 106, soil in the fields 104 may experience one or more soil conditions. As above, the sensors 114 are configured to also capture the soil data indicative of those conditions, and to communicate the soil data to the computing device 110, which in turn is configured to store the soil data in the repository 112. The soil data is associated with identifying data for the corresponding fields 104 (e.g., via field identifier, etc.), for example, to identify the specific soil data, over time, to the specific field(s).

The soil data, for example, may include, without limitation, measurements relating to organic matter (OM), cation exchange capacity (ccc), ph (e.g., acidity, etc.), sand content, clay content, silt content, available soil water capacity (volumetric fraction until wilting point, and bulk density, etc., which may be captured at one of more discrete times, or intervals, prior to, during, or after the growing of the plants 106 in the fields 104.

It should be appreciated that certain ones of the sensors 114 may be omitted from the fields 104, for example, for the weather data and soil data, as the computing device 110 may be configured to retrieve or otherwise access the weather data and/or soil data from a third-party service and to store the data in the repository 112 in association with identifying data for one or more of the fields 104 (e.g., via field identifier, etc.).

It should be further appreciated that additional types of data may be included in the repository 112 for the plants 106 and/or the fields 104, or region in which the fields 104 are located, etc. For example, the computing device 110 may be configured to receive or retrieve image data for the fields 104, prior to, during and/or after planting or harvest (or any time there between) of the fields 104, and to store the image data in the repository 112 in association with identifying data for one or more of the fields 104 (e.g., via field identifier, etc.) and/or plants 106 in the fields 104 (e.g., via plant identifiers, etc.), for example, to identify the specific image data, over time, to the specific field(s)/plant(s), etc. The image data may include red (R), green (G), blue (B), near-filed infrared (NIR) data, or any other suitable bands of data, or any derivation thereof (e.g., NDVI or other vegetative indexes, etc.). The sensors 114, in this regard, may be employed either in or near the fields 104, for example, as unmanned aerial vehicles (UAV) (e.g., drones, etc.), ground-based vehicles, or apart from the fields 104, as, for example, satellites, etc.

In addition to images, other types of data may include management data for the fields 104. Management data may include any indication of one or more management practices, such as, for example, treatments, irrigation, etc., to the fields 104, prior to, during or after the growing of the plants 106 in the fields 104. The data, again, may be received, retrieved, generated, etc. and included in the repository 112 and associated with identifying data for one or more of the fields 104 and/or plants 106 in the fields 104 (e.g., via field identifier, plant identifier, etc.), for example, to identify the specific management practice data, over time, to the specific field(s) 104 and/or plants 106 in the fields 104.

Further, other types of data may include data generated by, provided by, received from, etc. modalities such as novel sensors, etc. (e.g., multispectral data, data from aerial sensors and/or under canopy sensors, satellite data/information, in-field disease detection data, data from root sensors (e.g., sonar data, x-ray data, etc.), etc.).

As indicated above, further plants 106 in the plant breeding architecture 102 are bred, created, and/or generated, through different cycles, whereby different combinations of plants 106 and/or modifications of the plants are provided through various techniques, and the resulting plants 106 are planted and grown consistent with the above, in one or more different fields 104, etc. In this way, several generations of plants 106 are assessed in the fields 104, and the associated plant data, weather data, soil data, and/or other data is included in the repository 112 as indicative of the plants 106 and/or the conditions in which those plants 106 were planted, tested, harvested, etc. The repository 112, in this example embodiment, includes tens of millions of data points for hundreds of thousands or millions of plants.

To this point, for example, with regard to the phenotype plant data, the repository 112 may include upwards of two million data points for training and over a quarter of a million data points for validation, or more or less; etc. In addition, with regard to the weather data, the repository 112 may include upwards of five million data points in the time-series ERA and TWC weather dataset. With regard to the soil data, the repository 112 may include over forty-five thousand data points in the soil grid 250 dataset. Further, with regard to the genotype plant data, the repository 112 may include upwards of one hundred thousand germplasms including over one billion data points. With that said, in one example, the computing device 110 and repository 112 (e.g., the simulation architecture herein, etc.) may accommodate generation of over six trillion data points for approximately one-hundred fifty products across relative maturity 110 in the United States for six environmental years. And, in one particular application of such data, short corn car height may leverage the simulator architecture to provide predictions over ten historical years which are then classified into risk categories for product placement.

It should be appreciated that the data described above is merely exemplary and that other sizes or more of less data may be employed in the embodiments herein.

The data included in the repository 112, in this example embodiment, forms a training data set, in which a trait of interest is defined. The trait of interest may be defined by a breeder or other user, with an aim toward simulating different plants (apart from the fields 104) to be informed about the potential performance of the same and/or to make decisions related to the same. In connection with the trait of interest, the plant data, the weather data and the soil data, in the training data set, is linked to data indicative of the trait of interest. As such, for example, where the trait of interest is yield, the genotypic data is associated with specific yield for that particular plant having that sequence and its performance in the fields 104; the weather data is associated with specific yields from the fields 104; and the soil data is associated with specific yields from the fields 104.

In this example embodiment, the repository 112 may further be configured and/or structured to permit access to each of the plant data, the weather data and the soil data, separately, yet along with the associated trait of interest. That is, despite the link, the soil data in the training set, for example, is soil data plus yield data, but is not identified to any specific genotypic data or any weather data, in this example embodiment. In this manner, the training data set defines mode-specific data. As such, a weather mode includes weather plus the trait of interest; a soil mode includes soil data plus the trait of interest; and a plant mode includes plant data plus the trait of interest.

In connection with the training data set, it should be appreciated that dimensions of the data in the repository 112, for each mode, for example, may be adjusted, by the computing device 110, to provide for commonality and/or uniformity among or between features, etc. For example, where weather data includes multiple features over time, the time interval of the weather may be defined to permit the weather features from different fields 104 to have the same dimensions. This adjustment may be considered a type of normalization, which may be imposed, along with other suitable normalization techniques, for each different mode of data, as necessary or desired, to define the training data set. In another example, the genotypic data may be expressed as a matrix (or embedding, etc.), for each of the bases of the DNA of the specific plants 106, at specific markers, whole genome sequencing, protein information, expressions, gene editing technologies, etc.

In this example embodiment, the plant breeding architecture 102 is further configured to simulate the performance, in terms of the trait of interest, for one or more plants 106. Specifically, the computing device 110 includes, as shown in FIG. 1, a simulation architecture 118, which configures the computing device 110 to simulate different traits of interest.

As shown, in this example, the simulation architecture 118 includes a mode layer 120, in which multiple modes of data are input (individually or together) and an aggregation layer 122, in which the different modes are combined to provide a simulated output associated with the trait of interest. Specifically, the mode layer 120 includes multiple separate modes of data, which may each include one or more types of data (e.g., soil, weather, plant, trait, soil+weather, weather+trait, etc.) and which configures the computing device 110, for each mode, to convert the input data into latent data. The aggregate layer 122, in turn, configures the computing device 110 to receive the latent feature data as input (e.g., via feature fusion (e.g., a concatenation of the latent data features, etc.), etc.), including or based on the trait of interest, etc., and to generate an output based on the combined modes of latent data.

The mode layer 120 may include multiple models, such as, for example, without limitation, for each mode, a deep neural network (DNN) model, a convolutional neural network (CNN) model, a recurrent neural network (RNN) model, a generative pre-trained (GPT) model (e.g., the GPT-2, etc.), a multilayer perceptron (MLP) model, a long short-term memory (LSTM) model, and/or other suitable models. It should be appreciated that the type of model may be mode specific, whereby one mode of data may employ a DNN model, while another mode of data may employ a CNN model in the mode layer 120. The aggregate layer 122 may include a single model, such as, for example, a neural network, or more specifically, a feed forward neural network with residual connections, etc.

It should be appreciated that the specific organization of the two layers of the simulation architecture 118, as well as the type, number and/or structure of models included in the layers thereof, may be different in various different embodiments.

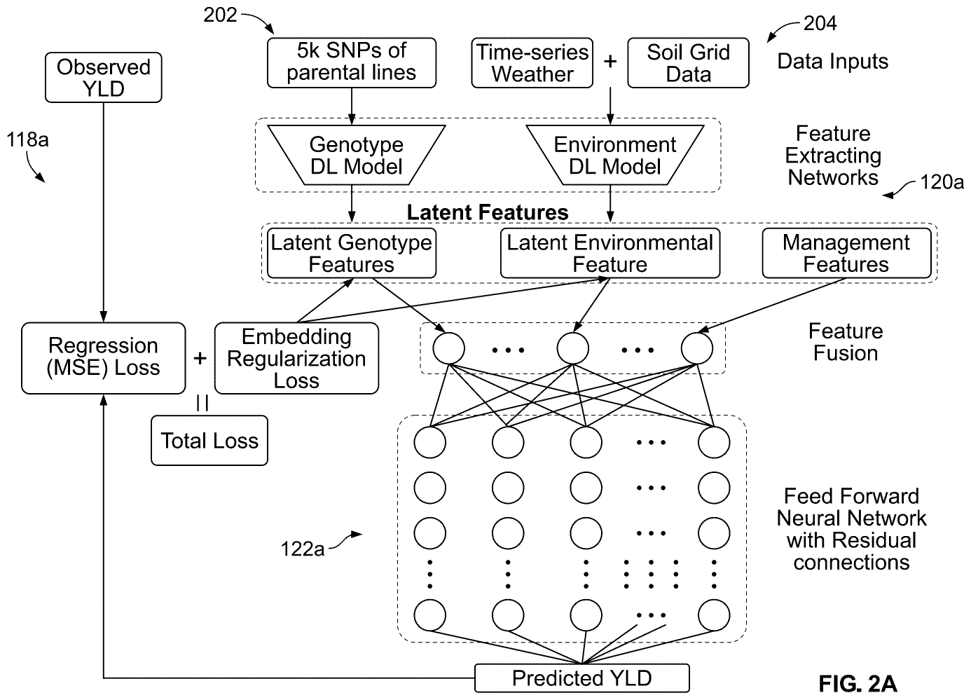

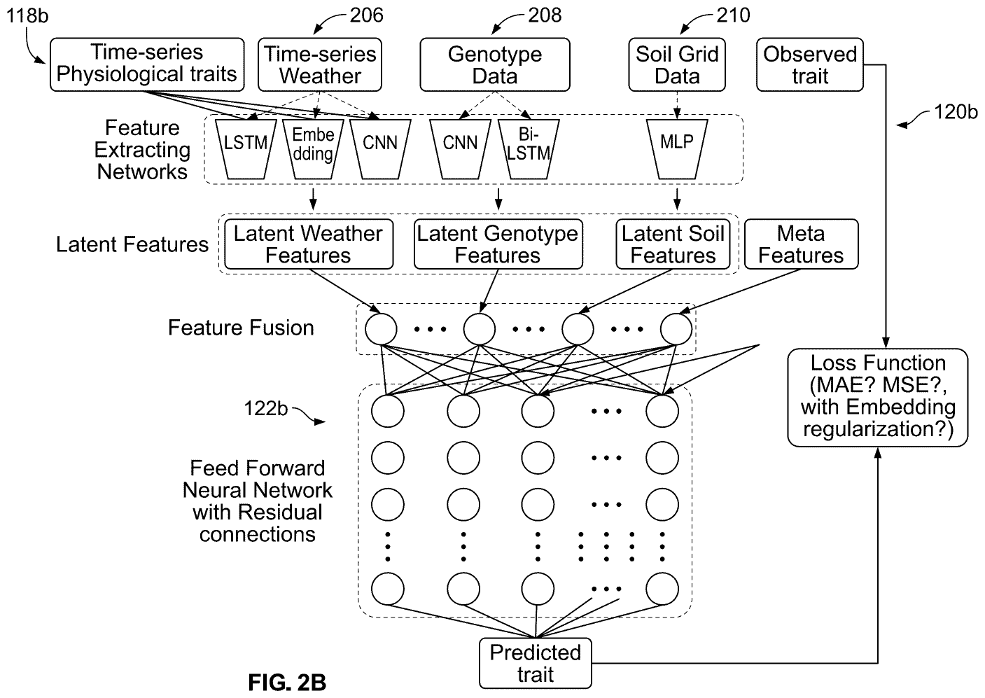

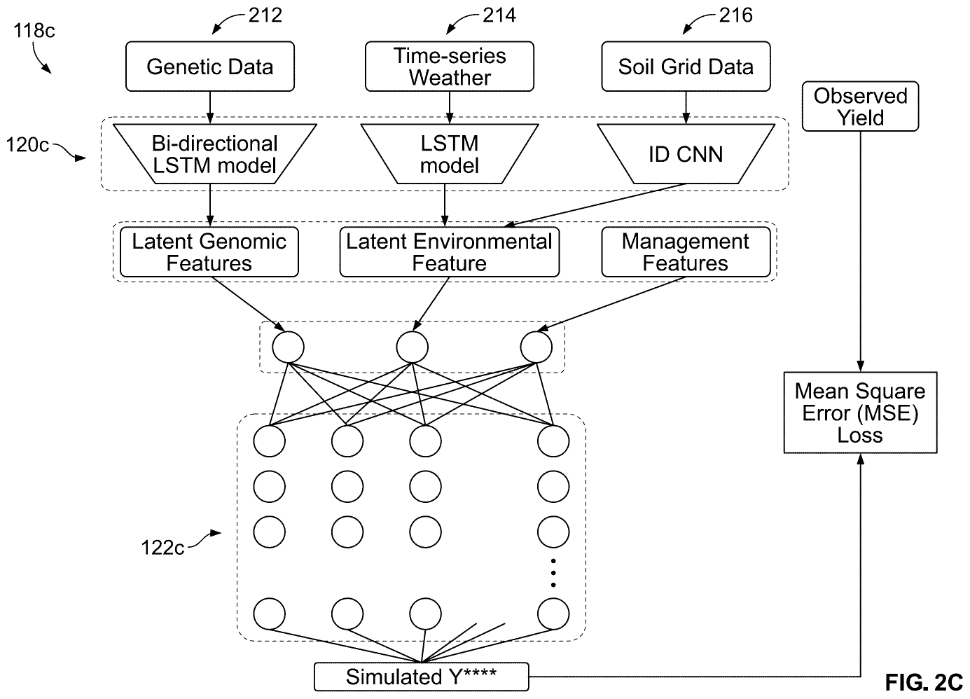

For example, FIGS. 2A-2C illustrate three example embodiments of the simulation architecture 118 (at 118a, 118b, and 118c). Each of the different simulation architecture embodiments is configured for a specific trait of interest and/or simulation scenario.

Specifically, as shown in FIG. 2A, a simulation architecture 118a includes a genotype mode 202 and an environmental mode 204 in the mode layer 120a, each of which have deep learning models. The genotype mode 202 may include, for example, a bi-directional LSTM model, which is configured to input SNPs from parental lines to generate latent genotypic feature data; and the environmental mode 204 may include a LSTM/RNN model, which is configured to input a combination of weather and soil data to generate latent environmental features. More generally, each of the modes 202, 204 includes a deep learning model. Further, as shown in FIG. 2A, the latent genotypic feature data, latent environmental feature data, and management practice data are combined (e.g., expressed as a concatenation of the latent features and trait of interest, etc.) in feature combination (or feature fusion) between the mode layer 120a and the aggregate layer 122a. The aggregate layer 122a, then, in this example, includes a feed-forward neural network, which is configured to generate a trait of interest output by combining the latent feature data from the mode layer 120a, via the feature data combination. More specifically, the neural network includes several nodes (e.g., hundreds, thousands, million of nodes, etc.), which are trained, as explained below, to produce a trait from input data, which in this example, is the latent data from the different modes. It should be understood that other types of neural networks, or other models may be included in the aggregate layer 122a in other simulation architecture embodiments otherwise consistent with FIG. 2A.

The simulation architecture 118a may be suited for predicting a specific trait, such as, for example, corn car height, etc. In such an implementation, the training data set may include data from over one hundred fields 104 and over ten thousand different hybrids 106, and may include over forty different weather features (e.g., as explained above, etc.), over five soil features and thousands of SNPs from the parental lines of the hybrids, etc.

It should be appreciated that the same or other input data and/or specific representation/combinations of that data, per mode, may be used in other implementations of the embodiment in FIG. 2A, and in still other embodiments other than (or beyond) FIG. 2A. For example, the weather data and the soil data may be separated into different mode models, whereby the mode layer 120a would include three different mode models.

In connection with training the simulation architecture 118 (e.g., the yield simulator, etc.), as described more below, a customized loss function may be used to guide the model to converge on the training dataset. In the illustrated embodiment, and without limitation, the loss function includes two components. The first component is a standard mean squared error (MSE) loss, which computes the mean of squares of errors between observed yields and predicted yields. The objective of the training procedure is to make this MSE loss as small as possible so that the predicted yields from model outputs are close to the observed yields in the inputs. The second component is the Cosine Similarity between the environmental latent vectors (e.g., of the environmental mode 204, etc.) and the genotype latent vectors (e.g., of the genotype mode 202, etc.), which serves as a regularizer during training. The range of this item is between −1 and 1. When it is a negative number between −1 and 0, 0 indicates orthogonality and values closer to −1 indicate greater similarity. When the model converges in the training, the value will close to −1, which indicates the environmental and genotype latent vectors are more aligned in the latent space, which can help the simulation architecture 118 better learn the interaction effect of genotype and environment.

With reference to FIG. 2B, a further example simulation architecture 118b includes a weather data mode 206, a genotype mode 208, and a soil mode 210 in the mode layer 120b. The weather mode 206 includes three different models: a LSTM model, an embedding model, and a CNN model. Each of the models is provided input data, which includes weather data and also time series physiological trait data (e.g., thermodynamics, biomass, leaf traits, plant growth measurements, etc.). Each is configured to generate latent weather feature data, based on the combination of the different models. Each dataset is combined to predict a trait or input to a physics based equation that is then reduced to a latent feature along with latent features from each data modality. The genotype mode 208 includes two models: a CNN model and a bi-directional LSTM model. Each of the models is configured to generate latent genotypic feature data. And, the soil mode 210 includes a MPL model, which is configured to generate latent soil feature data. In this example, the latent weather feature data, the latent genotypic feature data, the latent soil feature data, and the management practice data are combined in feature fusion between the mode layer 120b and the aggregate layer 122b. The aggregate layer 122b, then, includes a feed-forward neural network with residual connections, which is configured to generate a trait of interest output by combining the latent feature data from the mode layer 120b.

FIG. 2C illustrates a further example simulation architecture 118c, which includes a genetic data mode 212, a weather mode 214, and a soil mode 216 in the mode layer 120c. The genetic mode 212 includes a bi-directional LSTM model, which is configured to generate latent genetic feature data; the weather mode 214 includes a LSTM model, which is configured to generate latent weather feature data; and the soil mode 216 includes a one-dimensional CNN model, which is configured to generate latent soil feature data. As shown, the latent weather feature data and the latent soil feature data are combined into the latent environmental feature data. In this example, then, the latent genetic feature data, latent environmental feature data, and management practice data are combined in feature fusion between the mode layer 120c and the aggregate layer 122c. The aggregate layer 122c, then, includes a feed-forward neural network with residual connections, which is configured to generate a trait of interest output by combining the latent features from the mode layer 120c.

In still other example embodiments, the simulation architecture 118 may include other suitable techniques, such as, for example, Bayesian neural networks and conformal predictions, etc.

It should be appreciated that different data may be combined, per mode, or maintained separately, in other example embodiments, and that the modes illustrated in FIGS. 2A-2C may include different models therein in other embodiments.

Based on the above, the computing device 110 is configured to train the simulation architecture 118, in whole or in parts, based on the training data set. In this example embodiment, the computing device 110 is configured to input the data from the training data set to each of the models included in the mode layer 120, i.e., specific data per mode model, to be trained to the known trait of interest from the training data set, whereby the simulation architecture 118 is trained in this embodiment as a fully connected architecture. That said, it should be appreciated that in other embodiments, or in connection with updates based on additional data, the different models of the simulation architecture 118 may be trained individually, and then included in the simulation architecture 118. For example, each of the mode models in the mode layer 120 may be trained separately, based on the specific mode of data in the training data set and the trait of interest, and then, once trained, the mode models may be used, in connection with the aggregation layer to then train the model included in the aggregate layer 122.

Consistent with the above, the mode layer 120 and the aggregate layer 122, in combination, may provide for realization of hidden informative features in the intermediate, separate mode data.

Once trained, the computing device 110 is configured to validate the simulation architecture 118, again, either in parts or as a whole, based on a reserved portion of the training data set, i.e., a validation data set. Based on validation that the simulation architecture 118 provides a sufficient performance (e.g., based on one or more thresholds, etc.), the simulation architecture 118 is stored in the repository 112 for use in predicting the trait of interest based on data consistent with the input modes of data. Sufficient performance may be defined based on one or more accuracy levels, deviations, etc.

Thereafter, the computing device 110 is configured, by the trained simulation architecture 118, to simulate the performance, in terms of the trait of interest, based on input data. The input data may include data for a target plant or set of plants to be bred, etc. In this manner, the performance of the target plant(s) in terms of the trait of interest may be simulated, by the computing device 110, using the simulation architecture 118, for different weather conditions and/or soil conditions, for example, to define a preferred and/or target environment, for example.

It should be appreciated that the simulation architecture 118 may be used in a variety of different implementations to assess the potential performance of target plants, for various different purposes.

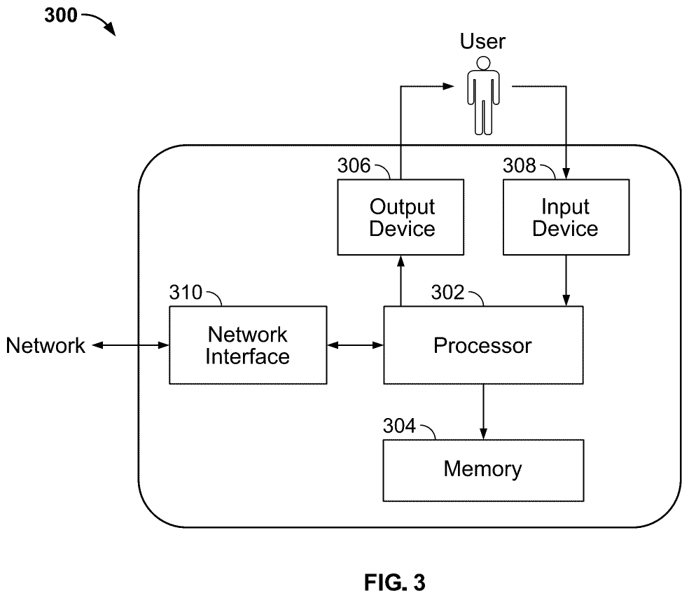

FIG. 3 illustrates an example computing device 300 that may be used in the system 100, for example, in connection with various phases of the plant breeding architecture 102. In connection therewith, the computing device 110 and/or the repository 112 may include and/or be implemented in at least one computing device consistent with computing device 300. In addition, the sensors 114, 116 and other components in the system may including and/or may be implemented in at least one computing device consistent with the computing device 300. In connection therewith, the computing device 300 may be uniquely, or specifically, configured, by executable instructions, to implement the various algorithms and other operations described herein with regard to the plant breeding architecture 102. It should be appreciated that the system 100, as described herein, may include a variety of different computing devices, either consistent with computing device 300 or different from computing device 300.

The example computing device 300 may include, for example, one or more servers, workstations, personal computers, laptops, tablets, smartphones, other suitable computing devices, combinations thereof, etc. In addition, the computing device 300 may include a single computing device, or it may include multiple computing devices located in close proximity or distributed over a geographic region, and coupled to one another via one or more networks. Such networks may include, without limitations, the Internet, an intranet, a private or public local area network (LAN), wide area network (WAN), mobile network, telecommunication networks, combinations thereof, or other suitable network(s), etc. In one example, the repository 112 of the system 100 includes at least one server computing device, which is coupled to the repository 112, directly and/or by one or more LANs, etc.

With that said, the illustrated computing device 300 includes a processor 302 and a memory 304 that is coupled to (and in communication with) the processor 302. The processor 302 may include, without limitation, one or more processing units (e.g., in a multi-core configuration, etc.), including a central processing unit (CPU), a microcontroller, a reduced instruction set computer (RISC) processor, an application specific integrated circuit (ASIC), a programmable logic device (PLD), a gate array, and/or any other circuit or processor capable of the functions described herein. The above listing is example only, and thus is not intended to limit in any way the definition and/or meaning of processor.

The memory 304, as described herein, is one or more devices that enable information, such as executable instructions and/or other data, to be stored and retrieved. The memory 304 may include one or more computer-readable storage media, such as, without limitation, dynamic random access memory (DRAM), static random access memory (SRAM), read only memory (ROM), erasable programmable read only memory (EPROM), solid state devices, flash drives, CD-ROMs, thumb drives, tapes, hard disks, and/or any other type of volatile or nonvolatile physical or tangible computer-readable media. The memory 304 may be configured to store, without limitation, weather data, soil data, genotypic data, latent feature data, traits of interest, models (e.g., trained, untrained, etc.), and/or other types of data (and/or data structures) suitable for use as described herein, etc. In various embodiments, computer-executable instructions may be stored in the memory 304 for execution by the processor 302 to cause the processor 302 to perform one or more of the functions described herein (e.g., one or more of the operations included in method 400, etc.), such that the memory 304 is a physical, tangible, and non-transitory computer-readable storage media. Such instructions often improve the efficiencies and/or performance of the processor 302 that is performing one or more of the various operations herein. It should be appreciated that the memory 304 may include a variety of different memories, each implemented in one or more of the functions or processes described herein.

In the example embodiment, the computing device 300 also includes an output device 306 that is coupled to (and is in communication with) the processor 302. The output device 306 outputs, or presents, to a user of the computing device 300 (e.g., a breeder, etc.) by, for example, displaying and/or otherwise outputting information such as, but not limited to, selected progeny, progeny as commercial products, traits of interest, performance metrics for plants, and/or any other types of data as desired. It should be further appreciated that, in some embodiments, the output device 306 may comprise a display device such that various interfaces (e.g., applications (network-based or otherwise), etc.) may be displayed at computing device 300, and in particular at the display device, to display such information and data, etc. And in some examples, the computing device 300 may cause the interfaces to be displayed at a display device of another computing device, including, for example, a server hosting a website having multiple webpages, or interacting with a web application employed at the other computing device, etc. Output device 306 may include, without limitation, a liquid crystal display (LCD), a light-emitting diode (LED) display, an organic LED (OLED) display, an “electronic ink” display, combinations thereof, etc. In some embodiments, output device 306 may include multiple units.

The computing device 300 further includes an input device 308 that receives input from the user. The input device 308 is coupled to (and is in communication with) the processor 302 and may include, for example, a keyboard, a pointing device, a mouse, a stylus, a touch sensitive panel (e.g., a touch pad or a touch screen, etc.), another computing device, and/or an audio input device. Further, in some example embodiments, a touch screen, such as that included in a tablet or similar device, may perform as both output device 306 and input device 308. In at least one example embodiment, the output device 306 and the input device 308 may be omitted.

In addition, the illustrated computing device 300 includes a network interface 310 coupled to (and in communication with) the processor 302 (and, in some embodiments, to the memory 304 as well). The network interface 310 may include, without limitation, a wired network adapter, a wireless network adapter, a telecommunications adapter, or other devices capable of communicating to one or more different networks. In at least one embodiment, the network interface 310 is employed to receive inputs to the computing device 300. For example, the network interface 310 may be coupled to (and in communication with) in-field data collection devices (e.g., one or more of the sensors 114, 116, etc.), in order to collect data for use as described herein. In some example embodiments, the computing device 300 may include the processor 302 and one or more network interfaces incorporated into or with the processor 302.

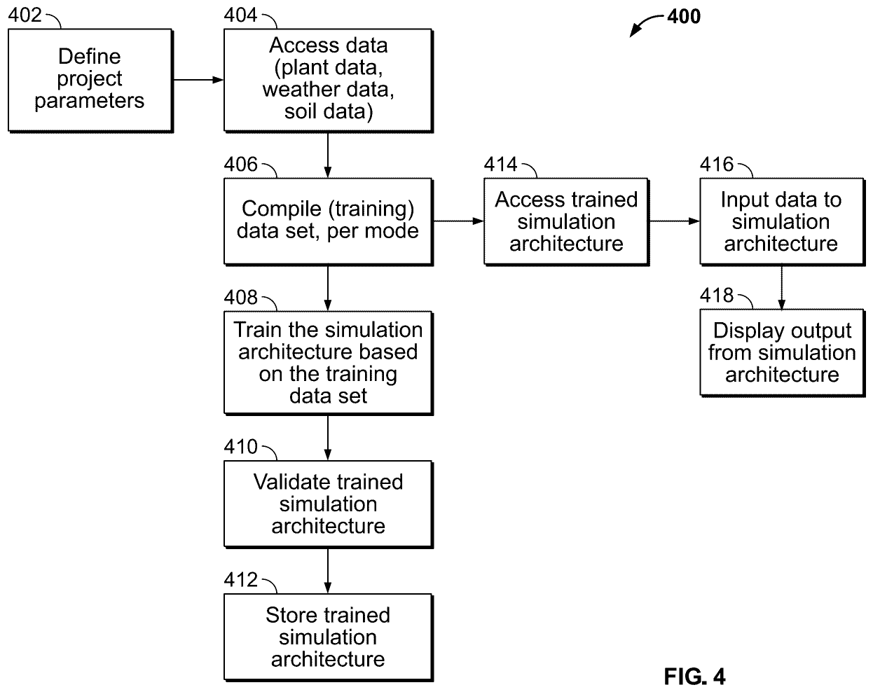

FIG. 4 illustrates an example method 400 of interpreting traits in agricultural crops, based on a multi-modal simulation architecture. The example method 400 is described herein in connection with the system 100, and may be implemented, in whole or in part, in the computing device 110 of the system 100. Further, for purposes of illustration, the example method 400 is also described with reference to the computing device 300 of FIG. 3. However, it should be appreciated that the method 400, or other methods described herein, are not limited to the system 100 or the computing device 300. And, conversely, the systems, data structures/repositories, and computing devices described herein are not limited to the example method 400.

To begin, a plant technician (or other user) (e.g., a breeder, a project manager, etc.) initially identifies a plant type (e.g., maize, soybeans, etc.) and a trait of interest for the plant (e.g., yield, height, etc.). The plant technician may also define a specific environment, for example, depending on the particular aim of the technician (e.g., in a placement scenario, versus a breeding scenario, etc.).

At 402, consistent with the above, a project to which method 400 is directed (e.g., for simulation, etc.) is associated with parameters, such as, for example, the plant type and trait of interest, etc., which are defined by the plant technician or other user. The parameters may be defined, at the computing device 110 (e.g., via input device 308, etc.), through one or more interfaces displayed at the computing device 110 (e.g., via output device 306, etc.).

The project parameters may also include an identification of the different modes of data to be included in the simulation of the trait of interest, and further, optionally, specific type(s) of models and/or a manner of connection of data in the specific modes. Specifically, for example, the parameters may define the models and/or specific setup or arrangement of the data, modes, and/or models, as illustrated across FIGS. 2A-2C. Like the above, the additional parameters may be defined, at the computing device 110, through one or more interfaces displayed at the computing device 110. In the example associated with method 400, for purposes of illustration, the simulation architecture 118c is defined by the parameters from the project.

At 404, the computing device 110, based on the parameters, accesses data, from the repository 112, for the project, which, in this example, includes the mode data (e.g., for each specified mode, etc.) and the associated trait of interest for the fields 104 and/or plants 106 reflected in the mode data. Table 1, below, illustrates the example mode data, which is accessed from the repository 112. It should be appreciated that the mode data included in Table 1 is example only, and that other mode may exist and/or may be provided/used in other example embodiments.

TABLE 1

| | | Trait of |
|---|---|---|
| Mode Data | Value | Interest |
| Mode 1: Genetic | | Yield |
| Marker_1 | [Base Pair Matrix] | 81 bu/acre |
| . . . | . . . | . . . |
| Mode 2: Weather | | |
| Average Temperature | 76° F. (or [Average | 85 bu/acre |
| | temp matrix]) | |
| . . . | . . . | . . . |
| Mode 3: Soil | | |
| organic matter (OM) | 17.6% | 76 bu/acre |
| . . . | . . . | . . . |

As shown above, the mode data includes various different features of the soil, weather, and genotypes of the fields 104 and/or plants 106 represented in the data. It should be appreciated that other features, within the specific types of data, or between the data, may be included. For example, an additional mode may be included in the mode layer 120c for image data and/or vegetative data.

Further, it should be appreciated that the data may be expressed otherwise in other examples. For example, weather data may be expressed in a time-series format, or otherwise. Often, the mode data is processed to provide for commonality, ranges, and/or scale between the modes, etc.

At 406, the computing device 110 compiles the data set, per mode. In connection with the simulation architecture 118c, the computing device 110 compiles genetic data, time-series weather data, and soil grid data, where each includes a number of features specific to the field/plant, and also a trait of interest, such as, for example, yield.

At 408, the computing device 110 trains the simulation architecture 118c. In connection therewith, in this example, each of the models in the mode layer 120c is trained separately (e.g., trained separately at the same time and then combined via feature fusion and trained together, etc.). The genetic model 212, or the bi-directional LSTM model, in FIG. 2C, is trained based on the genetic data and the trait of interest. The genetic model 212, accordingly, is trained to generate latent feature genotypic data, from the genetic data, whereby the latent feature genotypic data is associated with a specific yield (apart from weather or soil). Likewise, the LSTM model of the weather mode 214 is trained based on the weather data and the trait of interest, to generate latent feature weather data, from the weather data, whereby the latent feature weather data is associated with a specific yield (apart from genetics or soil). And, further, the one-dimensional CNN model of mode 216 is trained based on the soil data and the trait of interest, to generate latent feature soil data, from the soil data, whereby the latent feature soil data is associated with a specific yield (apart from genetics or weather).

It should be appreciated that, as part of the training, each trained model from the mode layer 120c may be validated to ensure sufficient performance, as defined, for example, by a percentage, deviation, etc. (e.g., relative to a threshold, etc.).

Further, as part of the training in method 400 in FIG. 4, the trained and validated model models 212, 214, and 216, for example, are included in the simulation architecture 118c (whereby the latent feature data for weather and soil are combined, but the latent genotypic feature data is retained separate (as shown in FIG. 2C), and then the training data set is provided, by the computing device 110, to the simulation architecture 118c to train the neural network model of the aggregate layer 122c. After the neural network model is trained, the computing device 110 validates the overall simulation architecture 110 based on a reserved portion of the training data set, at 410.

At 412, the trained simulation architecture 118c (and the models included therein) is/are stored in memory, such as for example, the repository 112, by the computing device 110.

Subsequently, for an unknown trait of interest, for example, where the historical environmental data is known, and the specific plant is subject to change, the plant technician is permitted to use the trained simulation architecture 118c to predict or interpret the trait of interest for a specific plant (which may not have been subject to a specific environment, etc.). That is, as part of the project, a specific genetic profile may be defined, whereby the optimal environment for that plant is undetermined.

In this example flow of the method 400, at 404, the mode data for the environmental modes (e.g., the weather mode 214 and the soil mode 216 of the architecture 118c, etc.) is accessed, from the repository 112, by the computing device 110. And, at 406, the mode data is compiled for the project. That is, the weather data and the soil data are accessed, and then the mode data for the genetic profile is defined (similar to the genetic data (e.g., base pair matrix, etc.), etc.).

Then, at 414, the trained simulation architecture 118c is accessed from the repository 112.

At 416, the mode data for genetics, soil, and weather are input to the simulation architecture 118c. In response, the computing device 110, as configured by the trained simulation architecture 118c, generates a trait of interest output, per specific data. That is, the yield is predicted for each of the specific environmental data. For example, the target genetic profile (as defined by the genetic data) may yield 85 bu/acre in a specific weather profile and soil profile, and then, 76 bu/acres in a different specific weather profile and soil profile, whereby specific environments are generally defined for the genetic profile in terms of the trait of interest. As shown in FIG. 4, the output from the simulation architecture is displayed, by the computing device 110 (e.g., via output device 306, etc.), at 418.

The plant technician may then define a preferred or optimal environment for the specific genetic profile, whether the genetic profile has been incorporated into a physical plant or not.

Thereafter, the simulation architecture 118 may be retrained and/or updated based on planting plants consistent with the genetic profile in one or more of the defined environments to test and/or validate the architecture. Additionally, or alternatively, the simulation architecture 118 may be used to predict the trait of interest for other genetic profiles, or conversely, to predict genetic profiles for specific environments, etc.

In view of the above, the unique systems and method described herein provide for advanced interpretation of traits of interest, which may be used to define specific genetic profiles, or environmental profiles, for plants. The plants are planted and harvested for one or more reasons, whereby the plants constitute agricultural crops. Further, by leveraging the multi-modal architecture, mode data may be permitted to direct specific outputs, and may not be limited in effect by other modes of data. In this manner, for example, hidden mode features may be extracted, via the mode-specific modeling, to provide for greater accuracy in interpreting the trait of interest in the context of, for example, placement, breeding, selection, planting, planning, allocation, etc. Further still, as it relates to plant development, the trained simulation architecture may provide for advanced decisions in breeding, whereby plants are more readily assessed, in silico, through the simulation architecture, rather than through physical testing in fields at later growth stages of the plants.

In addition, as described, in some example embodiments, the methods and systems herein may be used for de novo genome design, or design of novel, untested genomes that represent desired and/or optimal combinations of genomic elements that may result in desired and/or optimal performance in given environments and under given management practices associated with product concepts. In addition, in some example embodiments the methods and systems herein may provide Bayesian optimal experimental design for product testing; one or more tailored solutions with regard to interpretation of traits of an agricultural crop; outcome-based pricing and/or sales data; desired and/or optimized timing to marked for agricultural products; improved and/or enhanced product launch effectiveness; improved and/or enhance operational efficiency with regard to product development; demand shaping for interpretation of traits of an agricultural crop; new value pools of products and/or traits; etc.

With that said, it should be appreciated that the functions described herein, in some embodiments, may be described in computer executable instructions stored on a computer readable media, and executable by one or more processors. The computer readable media is a non-transitory computer readable media. By way of example, and not limitation, such computer readable media can include RAM, ROM, EEPROM, CD-ROM or other optical disk storage, magnetic disk storage or other magnetic storage device, or any other medium that can be used to carry or store desired program code in the form of instructions or data structures and that can be accessed by a computer. Combinations of the above should also be included within the scope of computer-readable media.

It should also be appreciated that one or more aspects of the present disclosure transform a general-purpose computing device into a special-purpose computing device when configured to perform the functions, methods, and/or processes described herein.

As will be further appreciated based on the foregoing specification, the above-described embodiments of the disclosure may be implemented using computer programming or engineering techniques, including computer software, firmware, hardware or any combination or subset thereof, wherein the technical effect may be achieved by performing at least one of the following operations: (a) compiling multiple data sets including a first mode of data and a second mode of data; (b) accessing a simulation architecture, which includes a mode layer and an aggregate layer connected to the mode layer, the mode layer including a first model and a second model; (c) inputting the first mode of data to the first model and the second mode of data to the second model, whereby latent feature data is generated by the mode layer and input to the aggregate layer; and/or (d) presenting an output, from the simulation architecture, which includes a trait of interest based on the first mode of data and/or the second mode of data.

Examples and embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail. In addition, advantages and improvements that may be achieved with one or more example embodiments disclosed herein may provide all or none of the above mentioned advantages and improvements and still fall within the scope of the present disclosure.

Specific values disclosed herein are example in nature and do not limit the scope of the present disclosure. The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may also be suitable for the given parameter (i.e., the disclosure of a first value and a second value for a given parameter can be interpreted as disclosing that any value between the first and second values could also be employed for the given parameter). For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, and 3-9.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When a feature is referred to as being “on,” “engaged to,” “connected to,” “coupled to,” “associated with,” “in communication with,” or “included with” another element or layer, it may be directly on, engaged, connected or coupled to, or associated or in communication or included with the other feature, or intervening features may be present. As used herein, the term “and/or” and “at least one of” includes any and all combinations of one or more of the associated listed items.

None of the elements recited in the claims are intended to be a means-plus-function element within the meaning of 35 U.S.C. § 112(f) unless an element is expressly recited using the phrase “means for,” or in the case of a method claim using the phrases “operation for” or “step for.”

Although the terms first, second, third, etc. may be used herein to describe various features, these features should not be limited by these terms. These terms may be only used to distinguish one feature from another. Terms such as “first,” “second,” and other numerical terms when used herein do not imply a sequence or order unless clearly indicated by the context. Thus, a first feature discussed herein could be termed a second feature without departing from the teachings of the example embodiments.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A system for use in interpreting traits of interest in agricultural crops, the system comprising:
a computing device including a memory and at least one processor;
wherein the memory includes executable instruction and a simulation architecture, which includes a mode layer and an aggregate layer, the mode layer including at least one first model for a first mode and at least one second model for a second model for a second mode, each of the at least one first model and the at least one second model configured to output latent feature data, specific to the first mode and the second mode, respectively, to the aggregate layer; and
wherein the at least one processor is configured, by the executable instructions, to:
access data from the memory, the accessed data including first data specific to the first mode and second data specific to the second mode;
input the first data to the at least one first model and the second data to the at least one second model; and
generate, via the simulation architecture, an output indicative of the first data and the second data.

2. The system of claim 1, wherein the first data is one of soil data, weather data, and genetic data; and
wherein the second data is another one of the soil data, the weather data, and the genetic data.

3. The system of claim 2, wherein the latent feature data for the first mode and the second mode is combined, prior to input to the aggregate layer.

4. The system of claim 1, wherein the at least one first model includes one or more of: a deep neural network (DNN) model, a convolutional neural network (CNN) model, a recurrent neural network (RNN) model, a generative pre-trained (GPT) model, a multilayer perceptron (MLP) model, and a long short-term memory (LSTM) model; and
wherein the at least one second model includes one or more of: a DNN model, CNN model, a RNN model, a GPT model, a MLP model, and a LSTM model.

5. The system of claim 1, wherein the aggregate layer includes a neural network model.

6. The system of claim 1, wherein the at least one processor is further configured to present the output on an output device, to a user.

7. The system of claim 1, wherein the output includes an environment in which to plant seeds associated with the first data and/or the second data.

8. A computer-implemented method for use in interpreting traits of interest in agricultural crops, the method comprising:
compiling multiple data sets including a first mode of data relating to an agricultural crop and a second mode of data relating to the agricultural crop;
accessing a simulation architecture, which includes a mode layer and an aggregate layer connected to the mode layer, the mode layer including a first model and a second model;
inputting the first mode of data to the first model and the second mode of data to the second model, whereby latent feature data is generated by the mode layer and input to the aggregate layer; and
presenting an output, from the simulation architecture, which includes a trait of interest for the agricultural crop based on the first mode of data and/or the second mode of data.

9. The computer-implemented method of claim 8, wherein the first mode of data includes one of soil data, weather data, and genetic data for the agricultural crop; and
wherein the second mode of data includes another one of the soil data, the weather data, and the genetic data for the agricultural crop.

10. The computer-implemented method of claim 9, wherein the first model includes one or more of: a deep neural network (DNN) model, a convolutional neural network (CNN) model, a recurrent neural network (RNN) model, a generative pre-trained (GPT) model, a multilayer perceptron (MLP) model, and a long short-term memory (LSTM) model; and
wherein the second model includes one or more of: a DNN model, CNN model, a RNN model, a GPT model, a MLP model, and a LSTM model.

11. The computer-implemented method of claim 9, wherein the latent feature data incudes latent feature data for the first model and latent feature data for the second model; and
wherein the computer-implemented method further comprises combining the latent feature data for the first model and the latent feature data for the second model, prior to input to the aggregate layer.

12. The computer-implemented method of claim 11, wherein the aggregate layer includes a neural network model.

13. The computer-implemented method of claim 8, further comprising presenting the output on an output device, to a user.

14. The computer-implemented method of claim 13, wherein the output includes an environment in which to plant seeds associated with the first mode of data and/or the second mode of data.

15. A non-transitory computer readable storage medium including executable instructions for use in interpreting traits of interest in agricultural crops, which, when executed by at least one processor, cause the at least one processor to:
compile multiple data sets including a first mode of data relating to an agricultural crop and a second mode of data relating to the agricultural crop;
access a simulation architecture, which includes a mode layer and an aggregate layer connected to the mode layer, the mode layer including a first model and a second model;
input the first mode of data to the first model and the second mode of data to the second model, whereby latent feature data is generated by the mode layer and input to the aggregate layer; and
present an output, from the simulation architecture, which includes a trait of interest for the agricultural crop based on the first mode of data and/or the second mode of data.

16. The non-transitory computer readable storage medium of claim 15, wherein the first mode of data includes one of soil data, weather data, and genetic data for the agricultural crop; and
wherein the second mode of data includes another one of the soil data, the weather data, and the genetic data for the agricultural crop.

17. The non-transitory computer readable storage medium of claim 16, wherein the first model includes one or more of: a deep neural network (DNN) model, a convolutional neural network (CNN) model, a recurrent neural network (RNN) model, a generative pre-trained (GPT) model, a multilayer perceptron (MLP) model, and a long short-term memory (LSTM) model; and
wherein the second model includes one or more of: a DNN model, CNN model, a RNN model, a GPT model, a MLP model, and a LSTM model.

18. The non-transitory computer readable storage medium of claim 17, wherein the latent feature data incudes latent feature data for the first model and latent feature data for the second model; and
wherein the executable instructions, when executed by the at least one processor, further cause the at least one processor to combine the latent feature data for the first model and the latent feature data for the second model, prior to input to the aggregate layer.

19. The non-transitory computer readable storage medium of claim 18, wherein the aggregate layer includes a neural network model.

20. The non-transitory computer readable storage medium of claim 19, wherein the output includes an environment in which to plant seeds associated with the first mode of data and/or the second mode of data.
